(19) United States
(12) Patent Application Publication
(10) Pub. No.: US 2026/0130172 A1
(43) Pub. Date: May 7, 2026

(54) Miniature Electrostatic Chuck for Die-to-Substrate Bonding and Method for Manufacturing the Same

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/939,538

(22) Filed: Nov. 7, 2024

(51) Int. Cl. H01L 21/683; H01L 21/67; H01L 21/68; H01L 21/768; H01L 23/48; H01L 23/544

(52) U.S. Cl. CPC H10P 72/722; H10P 72/0428; H10P 72/0446; H10P 72/53; H10W 20/023; H10W 20/20; H10W 46/00; H10W 46/301

(57) ABSTRACT

The present disclosure provides a miniature electrostatic chuck (ESC) for die-to-wafer (D2W) bonding. The ESC can be manufactured using conventional semiconductor processes, incorporating through-silicon-via (TSV) and through-dielectric-via (TDV) structures. The ESC with different sizes can be attached to and detached from a multi-axis robotic arm, allowing optimized D2W bonding processes.

### FIELD

The present invention relates to bonding heads used in semiconductor manufacturing, specifically to miniature electrostatic chucks (ESCs) designed for handling thin semiconductor dies in advanced die-to-substrate bonding processes.

### BACKGROUND

In advanced semiconductor packaging processes, handling and positioning thin dies, especially those susceptible to warpage, present critical challenges. Conventional bonding heads may lack the necessary control and stability for smaller, more delicate dies. The demand for a miniature ESC capable of securely holding such dies without damage has become increasingly important, especially as die thickness continues to decrease significantly.

Miniature ESCs address these challenges by providing localized electrostatic clamping force for small dies. The electrostatic clamping force generated by the ESC mitigates the effects of warpage, flattening the die onto the chuck surface and promoting more uniform contact. However, manufacturing such specialized ESCs can be costly, and replacing them often incurs significant time and expense. The high cost and rigid structure of custom ESCs also limit flexibility, restricting their applicability across different die sizes and increasing operational costs.

This invention introduces a miniature ESC fabricated using semiconductor manufacturing processes, yielding several distinct advantages. By leveraging well-established semiconductor fabrication techniques, production costs are reduced significantly, making the miniature ESCs affordable and accessible. The ability to fabricate ESCs in varying sizes provides flexibility, enabling a single miniature ESC to hold multiple dies simultaneously, if needed. Additionally, the ESC's detachable configuration simplifies replacement and maintenance, minimizing downtime and enhancing process efficiency. The detachable feature further improves adaptability, allowing for easy replacement when clamping surfaces degrade or adjustments in chuck size are required.

Thus, the invention meets the specific handling needs of thin and warped dies while enhancing cost-effectiveness, flexibility, and operational efficiency in advanced packaging processes.

### SUMMARY

The present invention provides a miniature ESC for a bonding head, designed to handle delicate semiconductor dies, including those prone to significant warpage. The miniature ESC applies an electrostatic clamping force that mitigates the effects of warpage, delivering a more uniform hold on the die surface and improving stability during semiconductor processing. This ESC is fabricated using semiconductor manufacturing processes and incorporates through-silicon via (TSV) and through-dielectric via (TDV) structures to establish effective electrical connectivity from a base silicon layer to electrodes embedded within a bulk dielectric layer and beneath a surface dielectric layer. In this process, TDVs are filled with conductive materials, such as copper or tungsten, and aligned with TSVs to facilitate reliable bias application to the electrodes, generating the electrostatic clamping force. These processes enable the ESC to be produced in customizable sizes, providing a cost-effective solution that supports various die sizes, including configurations where a single ESC can hold multiple dies simultaneously.

The bias voltage required for the electrostatic clamping force is supplied by a power source integrated into a supporting structure, which may include a rechargeable battery. This configuration allows for an independent power supply, eliminating the need for external wiring and enhancing the ESC's versatility. In some implementations, the ESC can be easily attached to or detached from the support structure, facilitating quick replacement and maintenance, reducing downtime, and enabling rapid adaptation to changing die-handling needs.

Additionally, alignment structures can be created on the ESC surface using semiconductor manufacturing processes to ensure precise die positioning. These alignment marks, in the form of an array, are integrated directly onto the ESC, supporting accurate and consistent die placement and further enhancing operational precision. By addressing the challenges of securely holding warped and sensitive dies with a scalable, economical, and flexible solution, the invention significantly improves cost efficiency, adaptability, and alignment precision in advanced semiconductor packaging processes.

### BRIEF DESCRIPTIONS OF THE DRAWINGS

The accompanying drawings illustrate the following:

FIG. 1: A schematic representation of an exemplary bonding head with a miniature ESC.

FIG. 2: A flowchart illustrating a manufacturing process for the ESC based on a semiconductor manufacturing process.

FIG. 3: A schematic diagram demonstrating the evolution of the ESC manufacturing process.

FIG. 4: A schematic diagram illustrating an alignment array on the surface of the ESC for accurately placing multiple dies.

FIG. 5: An example showcasing the placement of an AI chip system with multiple dies onto an ESC surface.

### DETAILED DESCRIPTIONS

This section provides detailed embodiments of the present invention to ensure a comprehensive understanding. Specific examples are provided for clarity, but modifications and variations that align with the claims are considered within the scope of this invention. Conventional methods and components are discussed where relevant to underscore the distinct features of the invention.

### Definitions

Miniature Electrostatic Chuck (ESC)—a compact support apparatus used to securely hold one or multiple dies for die-to-substrate bonding, using electrostatic clamping forces.
Through-Silicon Via (TSV)—A vertical electrical connection passing through the silicon wafer, commonly used to interconnect different layers or components in semiconductor devices.
Through-Dielectric Via (TDV)—A vertical electrical connection passing through dielectric layers to enable electrical connectivity between different layers or components in semiconductor devices.
Bulk Dielectric Layer—The primary insulating layer in the ESC, typically positioned above the silicon layer, providing electrical insulation and mechanical support.
Surface Dielectric Layer—The outermost dielectric layer of the ESC, often made of a ceramic material with specific thermal and dielectric properties that supports electrostatic clamping.
Johnsen-Rahbek (JR) Effect—A phenomenon used in some ESCs, where controlled current leakage enhances the electrostatic clamping force.
Electrostatic Clamping Force—The force generated by applying a DC bias to electrodes within the ESC, enabling secure die or substrate holding on the chuck surface.
Copper Pillar—A conductive structure within TSVs that serves as an electrical connector, facilitating connectivity across layers.
Liner—An insulating layer, often an oxide, deposited within vias (e.g., TSVs and TDVs) to isolate conductive components like copper pillars from surrounding structures, preventing electrical leakage.
Temporary Substrate—A detachable support substrate used during ESC manufacturing, providing stability or protection in certain processing steps.
Blanket Silicon Etching—A silicon etching process applied uniformly across the wafer surface, typically used to reveal TSVs.
Dicing Process—The separation process that divides the ESC structure into individual dies, utilizing mechanical or laser techniques.
Bias Voltage—The DC voltage applied to the ESC electrodes to create an electrostatic clamping force.
Multi-axis Robotic Arm—A robotic arm with multiple degrees of freedom, used to position the ESC with precision in three-dimensional space.
Alignment Array—A pattern, such as a 2D barcode or varied critical dimension (CD) grid, on the ESC surface to aid in precise die placement by providing positional information to an alignment system.
Reflectometry Sensor—A sensor used to measure optical signatures from the alignment array for determining ESC position relative to die placement.

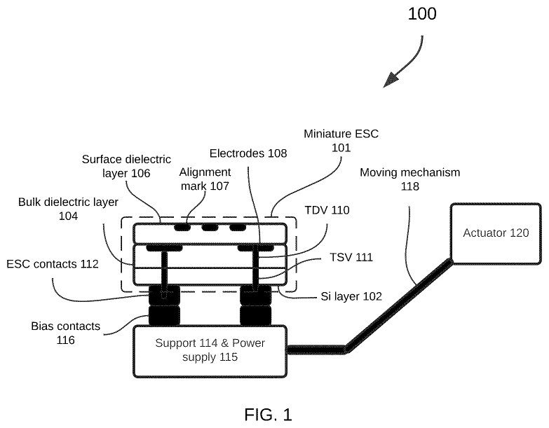

FIG. 1 illustrates a schematic representation of an exemplary bonding head, labeled as 100. The bonding head 100 includes a miniature ESC 101 attached to support 114. The support 114 includes a power supply 115, which provides a DC bias voltage for generating an electrostatic clamping force to hold a substrate on the top surface of the ESC 101. In some implementations, the power supply 115 is a rechargeable battery installed inside support 114. The support 114 is connected to a moving mechanism 118, which may be a multi-axis robotic arm. A 6-axis robotic arm is commonly used to allow precise 3D control, enabling movement along and rotation around the X, Y, and Z axes (roll, pitch, and yaw), making it ideal for tasks requiring complex positioning. The moving mechanism 118 is connected to an actuator 120.

The support 114 is coupled to ESC contacts 112 via bias contacts 116, which are conductive and provide the DC bias to the miniature ESC. These contacts can be made from various materials, including but not limited to copper, tungsten, aluminum, and tin-based alloys. In some implementations, the contacts may be surrounded by dielectric materials (not shown in FIG. 1). The support 114 may also generate another electrostatic clamping force to hold the ESC 101. For such implementations, the electrostatic clamping force that holds the support 114 and the ESC 101 together is temporary. The support 114 and the ESC 101 can be detached if the electrostatic clamping force is switched off. In other implementations, the ESC 101 and the support 114 are bonded permanently.

The ESC 101 is constructed from multiple layers of materials. Starting from the bottom, it includes a silicon layer 102, with a thickness that may range from 50 to 500 micrometers. Positioned on top of the silicon layer 102 is an ESC bulk dielectric layer 104, which may consist of materials including, but not limited to, silicon dioxide, alumina, and aluminum nitride, with a thickness ranging from 1 to 50 micrometers. On top of the bulk dielectric layer 104 is a surface dielectric layer 106, which may be a ceramic layer consisting of alumina or aluminum nitride. The thickness of the surface layer 106 may range from 0.1 to 1 micrometer. Electrodes 108 are positioned on the surface of the bulk dielectric layer 104 and are connected to ESC contacts 112 through an ESC via 110. The lower part of ESC via 110 is a TSV, while the upper part is a TDV. The electrodes 108 receive the DC bias voltage from the power supply 115, allowing the ESC 101 to generate an electrostatic force that holds one or more substrates on its surface. The substrate can be one or multiple dies. In the D2W bonding process, the dies involved are typically thin and exhibit significant warpage. The miniature ESC can steadily hold the dies and address issues caused by die warpage.

Optionally, an alignment mark 107 can be placed on the surface of the surface dielectric layer 106. These alignment marks can be formed using a semiconductor manufacturing process involving standard patterning and metallization processes.

The ESC 101 may have a surface area ranging from 4 mm² to 858 mm². The latter is approximately the size of a field in a lithography process.

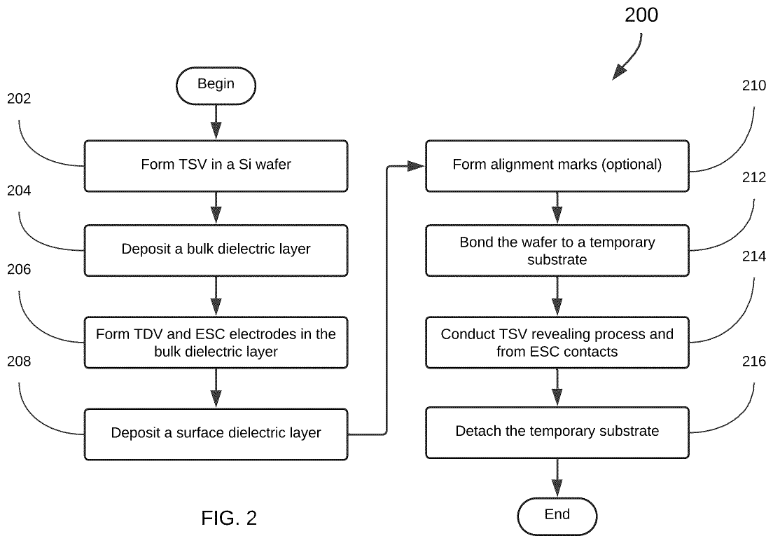

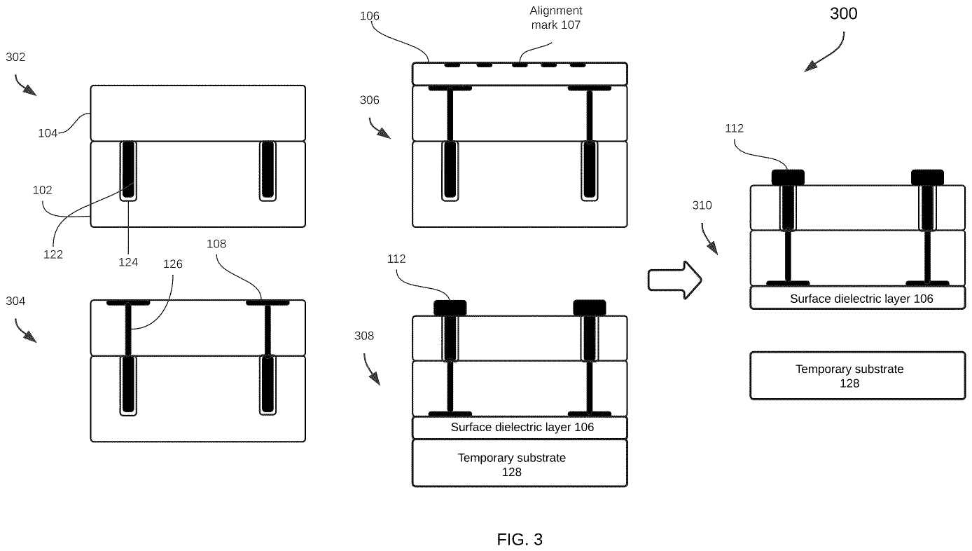

FIG. 2 depicts a flowchart illustrating a manufacturing process 200 for the miniature ESC based on semiconductor manufacturing processes. Process 200 begins with step 202, where TSV structures are formed on a silicon substrate, such as a 300 mm wafer. The TSV formation typically involves creating holes through patterning and etching steps. This is followed by the deposition of a liner 124, such as an ALD oxide layer, which serves as an insulator. Next, copper is used to fill the holes via a seed layer deposition and an electroplating process, followed by a copper CMP step to remove excess copper/seed layers on the surface. After CMP, copper pillars 122 are formed, as shown in 302 of FIG. 3. The liner 124 electrically isolates the copper pillar 122 from the silicon wafer. The depth of the copper pillars ranges between 50 and 500 micrometers. In another implementation, the TSV pillar 124 may be made from tungsten including a barrier layer like TiN, deposited using PECVD or ALD processes, followed by a CMP step to shape the pillars 122.

In step 204, the bulk dielectric layer 104, such as a dioxide layer with a thickness between 1 and 50 micrometers, is deposited using PECVD or CVD processes. Step 206 involves forming TDV structures through patterning and etching. The TDVs are aligned to the TSVs, although the TDV size may be smaller than the TSV to allow for some margin for misalignment due to the lithography process. It is crucial to ensure that the liner 124 remains undamaged during TDV etching to prevent leakage paths between the TSV pillars and the silicon wafer.

As shown in 304 of FIG. 3, the TDV holes are filled with the same metal as the TSV pillar 122. In some implementations, a barrier layer is formed between the TDV metal pillar and the bulk dielectric material. In one implementation, electrodes 108 are formed following the TDV process through patterning and metallization. In another implementation, the electrodes 108 are created concurrently with the TDV 126 using a dual-damascene process. The metal for the TDV and electrodes is deposited and polished in a dual-damascene process flow, as is common in the field.

In step 208, a surface dielectric layer 106, such as a ceramic material (e.g., alumina or aluminum nitride), is deposited, as shown in 306 of FIG. 3. Various deposition methods, including PECVD, CVD, and ALD, can be used in this step.

In one implementation, a Johnsen-Rahbek (JR) effect is used to generate the electrostatic clamping force. The JR ESC leverages the Johnsen-Rahbek effect, where a controlled current leakage enhances the electrostatic clamping force between the ESC and the substrate. For optimal JR ESC performance, the top ceramic layer must allow minimal but consistent leakage to sustain the JR effect. This layer should balance dielectric properties with slight conductivity, high thermal conductivity for heat dissipation, and strong resistance to plasma-induced wear. Additionally, it must have robust mechanical and chemical durability to withstand the harsh semiconductor processing environment.

Common materials for the top ceramic layer in a JR ESC include aluminum nitride (AlN) and alumina (Al₂O₃). Aluminum nitride is often favored for its high thermal conductivity, aiding in heat dissipation during processing. Alumina provides excellent dielectric properties, offering durability in challenging processing environments. Both materials can be engineered to support the controlled leakage necessary for the JR effect, balancing electrical conductivity with mechanical and chemical resilience for long-term stability.

The JR ESC does not require an external charge supply for clamping; instead, it relies on the inherent properties of the top ceramic layer to establish a stable electrostatic attraction through controlled charge leakage, maintaining the clamping force. This unique feature differentiates the JR ESC from other ESC types that depend on a continuous charge supply or higher voltages to achieve a similar effect.

The thickness of layer 106 may range from 0.1 to 1 micrometer. The DC bias voltage applied to the electrodes may range from 100V to 1000V.

In step 210, the silicon wafer is bonded to a temporary substrate 128 for the TSV revealing process. The temporary substrate 128 may be a glass substrate. Step 212 encompasses the TSV revealing process, which includes a blanket silicon etching sequence typically involving grinding, wet etching, and CMP. After the TSVs are revealed, ESC contacts 112 can be formed by depositing a metal layer, followed by a patterning and etching process. In another way, the ESC contacts can be formed by plating a metal pad through a defined photoresist patterns.

In step 214, the temporary substrate 128 is detached, as shown in 310 of FIG. 3, and the miniature ESCs are produced by separating the dies through a dicing process using mechanical force or laser cutting. In some implementations, plasma etching can also be used to separate the dies.

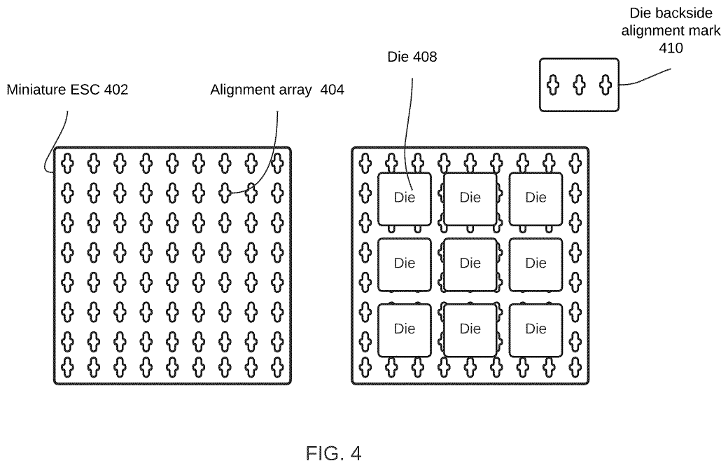

FIG. 4 shows a schematic diagram of the surface of a miniature ESC 402, which includes an alignment array 404. In one implementation, the alignment array comprises 2D barcodes. The 2D barcode is a matrix-style code that stores data in both the X and Y directions, typically comprising small squares, lines, or dots. For a specific position of the alignment array 404, an alignment device like a high precision camera can capture a spot image. The captured image is unique and can be compared to a set of pre-stored images to provide 2D positional information. A die to be placed onto the ESC 402 includes an alignment mark 408 on its back side. The alignment device guides the movement of the ESC 402 to receive the die in its designated position on the ESC surface. Multiple dies can be placed precisely onto the ESC surface.

In another implementation of the alignment array 404, a varied critical dimension (CD) grid is employed. The varied CD grid includes a 2D pattern where each spot on the grid has a unique arrangement of lines and spaces. When measured by the alignment device, such as a reflectometry sensor, the spot's unique optical signature provides 2D positional information for guiding the movement of the miniature ESC during the die placement process. The grid can be patterned using lithography techniques on the surface dielectric layer, with CD variations controlled to provide distinct optical signatures at various spots. The reflectometry spectrum for each spot may be pre-established and stored in a storage unit. Each spot's unique spectrum allows for precise determination of the ESC's position. The alignment device guides the ESC's movement by considering the measured position of the die using the backside alignment mark to precisely place the die on its designated position on the ESC surface.

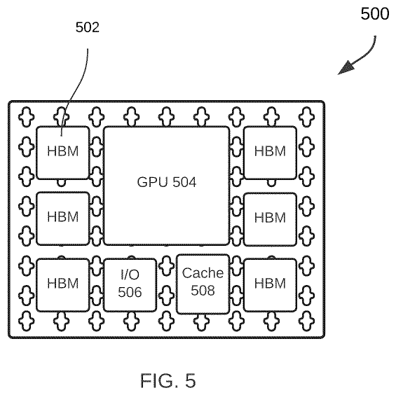

FIG. 5 showcases an example 500 of placing multiple dies of an AI chip system onto the ESC 402 surface. The AI chip system includes multiple HBMs 520, GPU 504, I/O 506, and cache 508. After placing the dies onto the surface of the ESC 402 in their designated positions, the dies can be bonded to an interposer collectively. For this collective die-to-substrate bonding, the height of each die needs to be consistent within a specified tolerance range.

1. A bonding head system for handling semiconductor dies, comprising:
a miniature ESC manufactured using a semiconductor manufacturing process, wherein the ESC includes a multi-layered structure comprising:
a silicon layer;
a bulk dielectric layer disposed on the silicon layer, providing electrical insulation;
a surface dielectric layer disposed on the bulk dielectric layer;
a conductive pathway formed through the silicon layer and the bulk dielectric layer, comprising TSVs and TDVs, configured to apply a DC bias voltage to electrodes below the surface dielectric layer to generate an electrostatic clamping force for holding one or more semiconductor dies; and
a support structure configured to detachably hold the miniature ESC and to supply the bias voltage; wherein the support structure is connected to a moving mechanism and wherein the semiconductor manufacturing process enables flexibility in the size of the miniature ESC.

2. The system of claim 1, wherein the moving mechanism includes a multi-axis robotic arm.

3. The system of claim 1, wherein the bulk dielectric layer has a thickness ranging from 1 micrometer to 50 micrometers.

4. The system of claim 1, wherein the bulk dielectric layer comprises a material selected from the group consisting of silicon dioxide, alumina, and aluminum nitride.

5. The system of claim 1, wherein the surface dielectric layer comprises a material selected from the group consisting of alumina and aluminum nitride.

6. The system of claim 1, wherein the surface dielectric layer is configured to provide controlled current leakage to enhance the electrostatic clamping force through the Johnsen-Rahbek (JR) effect.

7. The system of claim 1, wherein the TSVs and TDVs are filled with a conductive material selected from the group consisting of copper and tungsten.

8. The system of claim 1, further comprising alignment structures positioned on the surface dielectric layer to facilitate precise placement of semiconductor dies onto their designated positions.

9. The system of claim 1, wherein the miniature ESC has an area ranging from 4 mm² to 858 mm².

10. The system of claim 1, wherein the bulk and surface dielectric layers are deposited using a process selected from the group consisting of plasma-enhanced chemical vapor deposition (PECVD), thermal CVD, and atomic layer deposition (ALD).

11. The system of claim 1, wherein the DC bias voltage is provided by a rechargeable battery located in the support structure.

12. The system of claim 1, wherein the DC bias voltage is provided through the moving mechanism.

13. A method for manufacturing a miniature ESC for handling semiconductor dies, the method comprising:
forming TSVs in a silicon wafer;
depositing a bulk dielectric layer on the silicon wafer;
forming TDVs and electrodes on the bulk dielectric layer;
depositing a surface dielectric layer over the bulk dielectric layer;
bonding the silicon wafer to a temporary substrate;
conducting TSV revealing process and forming ESC contacts;
debonding the temporary substrate; and
separating the miniature ESCs through a dicing process.

14. The method of claim 13, wherein the bulk dielectric layer comprises a material selected from the group consisting of silicon dioxide, alumina, and aluminum nitride, and is deposited by using a PECVD or thermal CVD process.

15. The method of claim 13, wherein the surface dielectric layer comprises a material selected from the group consisting of aluminum oxide and aluminum nitride, and is deposited from a process selected from a group of the processes consisting of PECVD, thermal CVD, and ALD.

16. The method of claim 13, further comprising configuring the surface dielectric layer to allow controlled current leakage to generate an electrostatic clamping force through the Johnsen-Rahbek (JR) effect.

17. The method of claim 13, wherein the TSVs and TDVs are filled with a conductive material selected from the group consisting of copper and tungsten, with copper deposited through an electroplating process and tungsten deposited using a CVD or an ALD process.

18. The method of claim 17, further comprising removing a portion of copper or tungsten through a CMP process.

19. The method of claim 13, further comprising forming alignment structures on the surface dielectric layer.

20. The method of claim 19, wherein the alignment structures comprise a 2D barcode and a varied critical dimension (CD) grid.
